(19) United States
(12) Patent Application Publication
(10) Pub. No.: US 2023/0187549 A1
(43) Pub. Date: Jun. 15, 2023

(54) SELECTIVE GATE CAP FOR SELF-ALIGNED CONTACTS

(71) Applicant: International Business Machines Corporation, Armonk, NY (US)

(72) Inventors: Ruilong Xie, Niskayuna, NY (US); CHANRO PARK, CLIFTON PARK, NY (US); Julien Frougier, Albany, NY (US); Kangguo Cheng, Schenectady, NY (US); Eric Miller, Watervliet, NY (US); Ekmini Anuja De Silva, Slingerlands, NY (US)

(21) Appl. No.: 17/644,100

(22) Filed: Dec. 14, 2021

(51) Int. Cl. H01L 29/78; H01L 29/66; H01L 29/40

(52) U.S. Cl. CPC H01L 29/7831; H01L 29/401; H01L 29/66545

(57) ABSTRACT

A semiconductor device having a self-aligned contact gate dielectric cap, or “SAC cap” over the gate stack and spacer. A SAC cap ear exists over the sidewall of a top portion of the spacer at a location where no S/D contact is formed. A method of forming the semiconductor device comprises: (i) forming gate stack; (ii) recessing ILD to create topography of the gate stack; (iii) forming selective gate cap deposition over the gate stack; and/or (iv) forming self-aligned contact with respect to the selective gate cap.

### BACKGROUND

The present invention relates generally to the field of semiconductor manufacturing, and more particularly to fabricating self-aligned contacts with small gate pitch for field-effect transistor (FET) technologies beyond 5 nm.

As semiconductor devices shrink in each generation of semiconductor technology, formation of contact structures to source and drain regions of a field effect transistor become challenging because such contact structures not only need to provide reliable electrical contact to the source and drain regions, but also need to avoid electrically shorting to other components such as the gate electrode of the field effect transistor. Because the etch chemistry employed for the source/drain contact etch process remains the same while the lateral dimension between the source/drain contact and the gate shrinks with the scaling of semiconductor devices, the likelihood of overlay variations during lithographic processes causing formation of contact structures that electrically short a source/drain region to a gate conductor of a field effect transistor increases in each generation.

Further, contact structures to source and drain regions must avoid electrically shorting to gate conductors to provide a functional field effect transistor. Accordingly, the possibility of electrically shorting source/drain regions to a gate conductor of a field effect transistor is a significant concern for product yield and reliability purposes.

### SUMMARY

According to an aspect of the present invention, a semiconductor structure for transistors includes: an active gate over an active channel with active spacers formed at each sidewall of the active gate; a dummy gate over an end of an active region with a first spacer formed at a first sidewall of the dummy gate and a second spacer formed at a second sidewall of the dummy gate, the first spacer being located over the active region, the second spacer being located away from the end of the active region by the dummy gate; a first gate cap formed over the dummy gate, the first gate cap having a first cap width at a location above the dummy gate; a second gate cap formed over the active gate, the second gate cap having a second cap width at a location corresponding to the first cap width, the first cap width being larger than the second cap width; and a dielectric cap ear formed over the second sidewall of the dummy gate.

According to another aspect of the present invention, a semiconductor structure for transistors includes a source/drain contact formed between an active spacer and the first spacer of the dummy gate.

According to an embodiment, a method for producing a semiconductor device is provided. The method including forming a replacement gate stack with a gate spacer and a first interlayer dielectric in between gate spacers of neighboring devices; creating topography of the gate stack by recessing the first interlevel dielectric layer; forming a selective gate cap deposition over the gate stack; and forming a self-aligned contact with respect to the selective gate cap.

According to another embodiment, a method further includes patterning trenches in a second interlevel dielectric layer formed over the selective gate cap deposition and between the gate stack topography, exposing a source/drain region in the trenches and trimming the selective gate cap to align with a first sidewall of the spacer adjacent the source/drain region. The selective gate cap includes a cap extension over a second sidewall of the spacer where no source/drain contact is adjacent.

According to yet another embodiment, a method further includes filling the trenches to form source/drain metal contact plugs; removing the selective gate cap deposition to form a gate cap cavity; and filling back the gate cap cavity with a replacement dielectric; and forming contact via contacts through a third interlevel dielectric layer formed over the source/drain contacts and the replacement dielectric, the contact via contacts making electrical contact with the source/drain contact plugs.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a cross-sectional view of a semiconductor structure at an intermediate stage of fabrication, according to an exemplary embodiment;

FIG. 2 illustrates a cross-sectional view of the semiconductor structure and illustrates a recessed inner layer dielectric and formation of a selective gate cap deposition, according to an exemplary embodiment;

FIG. 3 illustrates a cross-sectional view of the semiconductor structure and illustrates etching a contact formation region and forming the selective gate cap to align with certain sidewalls of the spacers; according to an exemplary embodiment;

FIG. 4 illustrates a cross-sectional view of the semiconductor structure and illustrates formation of TS contacts, according to an exemplary embodiment;

FIG. 5 illustrates a cross-sectional view of the semiconductor structure and illustrates removal of the gate cap deposition, according to an exemplary embodiment; and

FIG. 6 illustrates a cross-sectional view of the semiconductor structure and illustrates a self-aligned contact structure adjacent a replacement dielectric filling the cavity of the removed gate cap deposition, according to an exemplary embodiment.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numbers may be repeated among the figures to indicate corresponding or analogous features.

### DETAILED DESCRIPTION

A semiconductor device having a self-aligned contact gate dielectric cap, or “SAC cap” over the gate stack and spacer. A SAC cap ear exists over the sidewall of a top portion of the spacer at a location where no S/D contact is formed. A method of forming the semiconductor device comprises: (i) forming gate stack; (ii) recessing ILD to create topography of the gate stack; (iii) forming selective gate cap deposition over the gate stack; and/or (iv) forming self-aligned contact with respect to the selective gate cap.

Using a work function metal (WFM) recess is a challenge for highly scaled gates. Some embodiments of the present invention do not require recessing WFM but directly for selective dielectric deposition over the gate for self-aligning contacts. According to some embodiments of the present invention, a replacement gate dielectric cap for MOL contact of horizontal FETs is formed using topographic selective deposition.

Some embodiments of the present invention recognize the following facts, potential problems and/or potential areas for improvement with respect to the current state of the art: (i) we have fundamental issue to form a self-aligned contact cap or “SAC cap” over the gate for beyond 5 nm since channel length (Lg) is too small, and there is no reliable way to do work function metal (WFM) recess at very small gate dimension; (ii) the need for a SAC cap increases initial dummy gate height which can lead to issues such as gate bending or gate collapse.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, terms such as “depositing”, “forming”, and the like may refer to the disposition of layers, or portions of materials, in accordance with a given embodiment. Such processes may or may not be different than those used in the standard practice of the art of semiconductor device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, wet and/or dry etching processes, plasma etching processes, or any of the known etching processes in which material is removed.

Those skilled in the art understand that many different techniques may be used to add, remove, and/or alter various materials, and portions thereof, and that embodiments of the present invention may leverage combinations of such processes to produce the structures disclosed herein without deviating from the scope of the present invention.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Some embodiments of the present invention are directed to a semiconductor device having a self-aligned contact gate dielectric cap, or “SAC cap” over the gate stack and spacer and a SAC cap extension exists over the sidewall of a top portion of the spacer at a location where no S/D contact is formed. Further, some embodiments of the present invention are directed to a structure and method to form SAC cap without the need of recessing the WFM.

Some embodiments of the present invention are directed to a method of forming a semiconductor device comprising the following steps: (i) forming gate stack; (ii) recessing ILD to create topography of the gate stack; (iii) forming selective gate cap deposition over the gate stack; and/or (iv) forming self-aligned contact with respect to the selective gate cap.

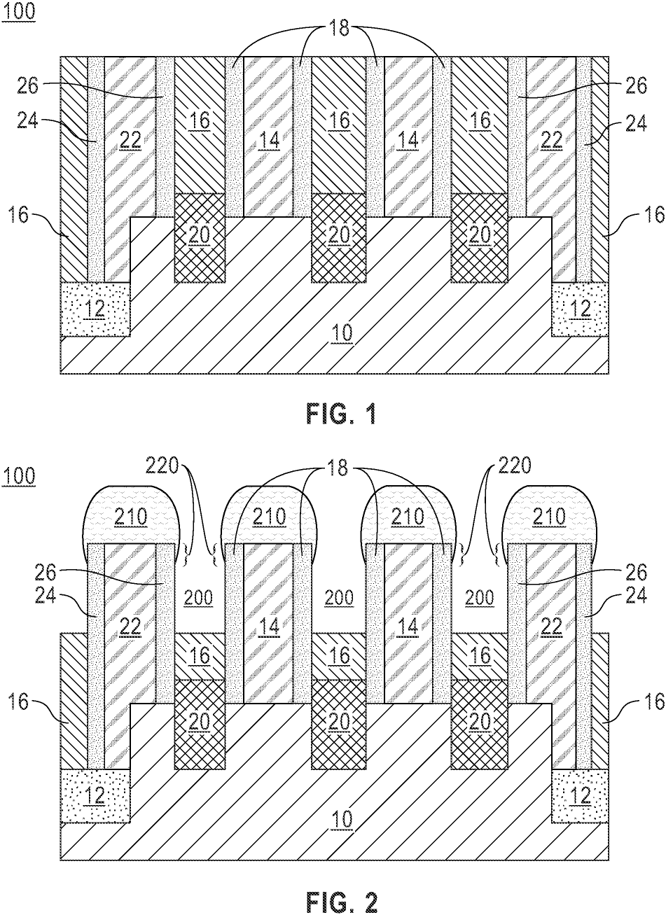

Some embodiments of the present invention disclose a structure and a method of forming selective gate cap deposition and a self-aligned contact with respect to the selective gate cap are described in detail below by referring to the accompanying drawings in FIGS. 1-6, in accordance with an illustrative embodiment.

Improvements to semiconductor manufacturing described herein are illustrated after initial development of a horizontal FET, as presented in FIG. 1, in a manner known in the art including conventional interlayer dielectric (ILD) formation 16, active gate formations 14 and dummy gate formations 22 including a gate dielectric, work function metals (WFM), and optional conductive metals and a polishing process such as a chemical mechanical polishing (CMP) technique to remove excess material and polish upper surfaces of semiconductor structure 100. Other features of the illustrated semiconductor structure include: semiconductor substrate 10, shallow trench isolation (STI) structure 12, dielectric gate spacers 18, 24, 26, and source/drain epitaxial growth regions 20. FIGS. 2-6 follow to illustrate various steps associated with embodiments of the present invention.

Referring now to FIG. 2, the ILD is recessed to a level that is below the top surface and a selective gate cap deposit is formed. Recess 200 is formed in the ILD, removing a portion of the ILD using, for example, a wet etching process that includes, for example, hydrofluoric acid (HF), buffered hydrofluoric acid (BHF), hydrofluoric nitric acid (HNA), phosphoric acid, or any combination thereof. The depth of the recess ranges from 20 nm to 50 nm.

Selective gate cap deposition produces a gate cap 210 on top of the existing gate structure such that overlapping condition, or dielectric cap ear, 220 develops. The selective gate cap can be formed using a topological selective deposition such that deposition of the material only happens at top surfaces of the pillars and the deposition rate dramatically decreases from top to bottom surfaces. In that way, there exists thin overlapping region 220 in the formation of selective gate caps 210 over the top portion of the side surface of outer gate spacers 24 as well as other gate spacers 26 and 18. One example of the selective gate cap material could be TiOx.

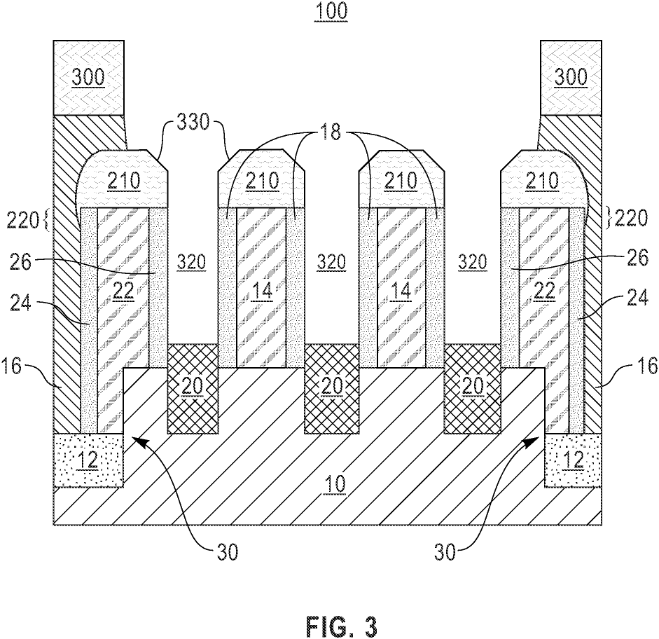

Referring to FIG. 3, an ILD 16 fill is deposited, covering selective gate caps 210, such as TiOx caps, and filling recesses 200. Organic planarization layer (OPL) 300 can be deposited above ILD 16 as part of the conventional lithographic stack, or litho stack. A source/drain contact opening 320 is formed by a process using a conventional lithography and etching process. For example, reactive ion etching (RIE) patterning creates source/drain contact opening 320 for source/drain contacts. The source/drain contact etch may cause corner loss features 330 to appear in the selective gate caps 210. Dielectric cap ears 220 of the selective gate caps remain on the dummy gates 22 at the outside ends, or beyond the ends of the active region 30, of structure 100 at outer gate spacers 24 where no source/drain contact etching occurs. The active region may be marked by the location of the STI structure 12.

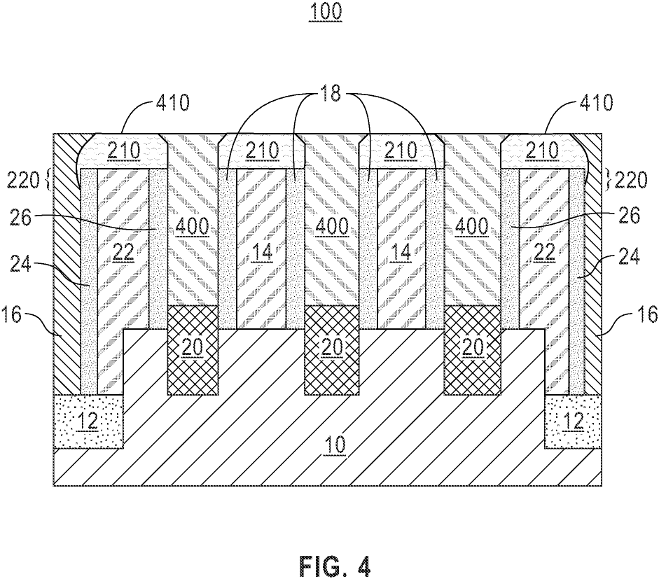

Referring to FIG. 4, source/drain contacts 400 are formed in source/drain contact openings 320 by a metallization process and a CMP process is applied to create top surface 410. In this disclosure, the source/drain contact metallization usually comprises: a silicide liner, such as Ti, Ni, NiPt, etc.; a metal adhesion layer, such as TiN; and conductive metal fills, such as W, Ru, Al, Co, etc. After metal deposition 400, a CMP process is applied to remove excessive metals over the selective gate cap 210 to create surface 410. In some embodiments of the present invention, the CMP process reduces the height of the selective gate cap, as shown in the figures.

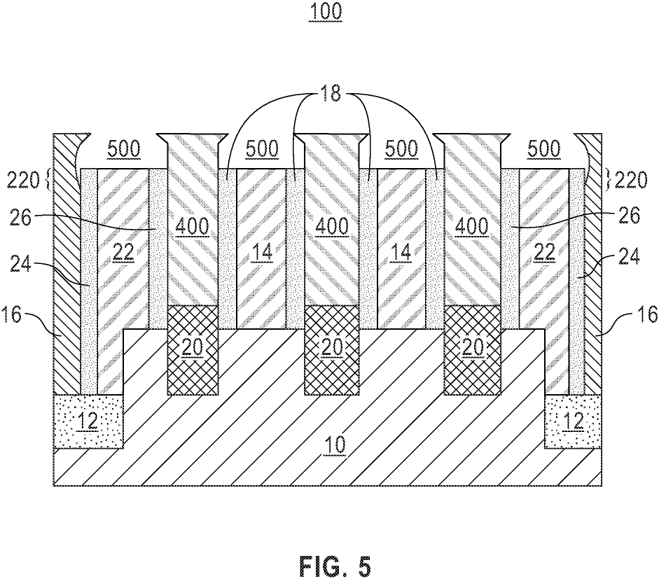

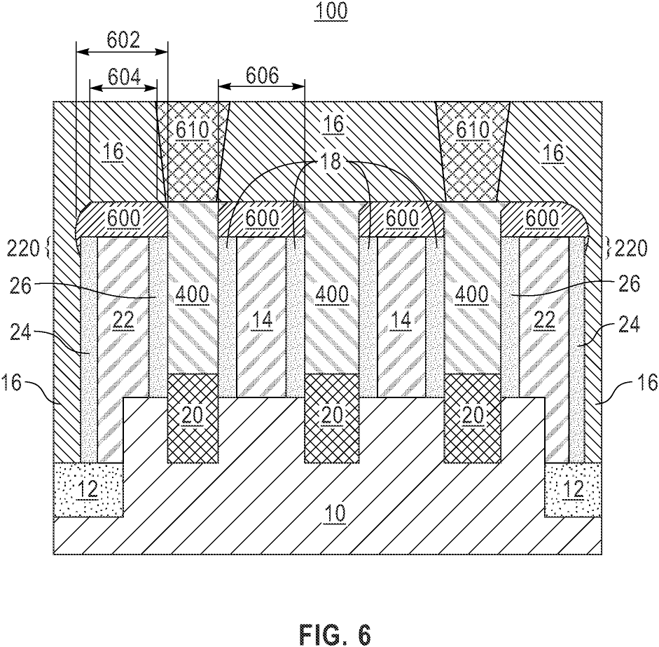

Referring to FIG. 5, the selective gate cap 210 is removed, leaving cavity 500 to be filled back with an appropriate dielectric material for the final SAC cap. Referring to FIG. 6, the cavity 500 is filled with dielectric material 600, additional ILD material 16 is added, covering the final SAC cap 600, and contact vias 610 are formed. The contact vias 610 extend through the ILD layer 16 to contact the source/drain contacts 400, and it can be part of middle of contact structures of first BEOL via level, which wires source/drain contact to BEOL interconnect levels. The cavity 500 may be filled with metals including Ru, W, Co, or Cu to form the final SAC cap 600. In some embodiments, an adhesion metal liner such as TiN or TaN is needed. In some other embodiments, no metal adhesion layer is present.

Some embodiments of the present invention are directed to a SAC cap over the gate stack and spacer and a SAC cap extension, or ear, over the sidewall of a top portion of the spacer where no S/D contact is formed.

Referring again to FIG. 6, some embodiments of the present invention are directed to a semiconductor device including: (i) transistors with active gates 14 over active channels and dummy gates 22 over the ends 30 of active regions; (ii) spacers 18, 24, 26 are formed at sidewalls of both the active gates and the dummy gates; (iii) source/drain epi 20 and source/drain contacts 400 are formed between gate spacers; (iv) dielectric gate caps 600 are formed over both the active gates and the dummy gates, with the top cap distance 604 being smaller than the bottom cap distance 602; (v) a dielectric cap ear 220 (also referred to as cap extension and cap overlap) is formed over the sidewall of the top portion of the gate spacer 24 of the dummy gates 22, the dielectric cap ear 220 is not next to the source/drain contacts 400. According to some embodiments of the present invention, the dielectric cap ear is not touching the source/drain contacts. Alternatively, the dielectric cap ear 220 is spaced apart from a source/drain contact 400 by the dummy gate 22.

Some embodiments of the present invention are directed to a semiconductor device as described above and further defined by the dielectric cap 600 of the dummy gate 22 having a bottom cap distance 602 that is larger than the bottom cap distance 606 of dielectric caps 600 of active gates 14. The bottom cap distance of the dummy gate includes the dielectric cap ear, which is not present on the dielectric caps of the active gates.

Some embodiments of the present invention may include one, or more, of the following features, characteristics and/or advantages: (i) no need to reserve gate height for SAC (sacrificial gate) cap in the beginning, thus saving gate height and avoiding gate bending; (ii) no need complex process like work function metal (WFM) recess; and/or (iii) no gate height or SAC cap variation caused by WFM recess variation at small channel length (Lg).

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure for transistors comprising:
an active gate over an active channel with active spacers formed at each sidewall of the active gate;
a dummy gate over an end of an active region with a first spacer formed at a first sidewall of the dummy gate and a second spacer formed at a second sidewall of the dummy gate, the first spacer being located over the active region, the second spacer being located away from the end of the active region by the dummy gate;
a first gate cap formed over the dummy gate, the first gate cap having a first cap width at a location above the dummy gate;
a second gate cap formed over the active gate, the second gate cap having a second cap width at a location corresponding to the first cap width, the first cap width being larger than the second cap width; and
a dielectric cap ear formed over the second sidewall of the dummy gate.

2. The semiconductor structure of claim 1, further comprising:
a source/drain contact formed between an active spacer and the first spacer of the dummy gate.

3. The semiconductor structure of claim 1, wherein:
the first gate cap has a top portion and a bottom portion;
the bottom portion of the first gate cap is located closer the gate than the top portion; and
the bottom portion is wider than the top portion.

4. The semiconductor structure of claim 1, wherein:
the dielectric cap ear located below an interface between the first gate cap and the dummy gate.

5. A method of forming a semiconductor structure comprising:
forming a replacement gate stack with a gate spacer and a first interlayer dielectric in between gate spacers of neighboring devices;
creating topography of the gate stack by recessing the first interlevel dielectric layer;
forming a selective gate cap deposition over the gate stack; and
forming a self-aligned contact with respect to the selective gate cap.

6. The method of claim 5, wherein:
the selective gate cap deposition is formed by topographic selective deposition.

7. The method of claim 5, further comprising:
patterning trenches in a second interlevel dielectric layer formed over the selective gate cap deposition and between the gate stack topography, exposing a source/drain region in the trenches and trimming the selective gate cap to align with a first sidewall of the spacer adjacent the source/drain region;
wherein:
the selective gate cap includes a cap extension over a second sidewall of the spacer where no source/drain contact is adjacent.

8. The method of claim 7, further comprising:
filling the trenches to form source/drain metal contact plugs;
removing the selective gate cap deposition to form a gate cap cavity; and
filling back the gate cap cavity with a replacement dielectric.

9. The method of claim 8, further comprising:
forming contact via contacts through a third interlevel dielectric layer formed over the source/drain contacts and the replacement dielectric, the contact via contacts making electrical contact with the source/drain contact plugs.
